(19) United States
(12) Patent Application Publication
(10) Pub. No.: US 2002/0166508 A1
(43) Pub. Date: Nov. 14, 2002

(54) Vacuum deposition system and thin-film deposition process

(76) Inventors: Ryuji Biro, Kanagawa (JP); Minoru Otani, Saitama (JP)

Correspondence Address: FITZPATRICK CELLA HARPER & SCINTO, 30 ROCKEFELLER PLAZA, NEW YORK, NY, 10112, US

(21) Appl. No.: 10/098,569

(22) Filed: Mar. 18, 2002

(30) Foreign Application Priority Data
Mar. 21, 2001 (JP) 080778/2001

(51) Int. Cl. C23C 16/00

(52) U.S. Cl. 118/726; 118/723 IR; 118/723 ME; 118/723 R

(57) ABSTRACT

A vacuum deposition system comprises i) a film-forming chamber the inside of which can be kept at a stated degree of vacuum by a film-forming chamber evacuation means such as a vacuum pump, having a substrate holder which holds a substrate on which a thin film is to be formed and a crucible which heats and evaporates a deposition material to be made into a thin film, and ii) a reaction chamber in the inside of which a gas is to be ionized, which is connected to a reaction chamber gas feed means which feeds a source gas for compensating gas atoms having come short; the film-forming chamber and the reaction chamber being connected through a pressure control means. The source gas fed by means of the reaction chamber gas feed means is previously ionized in the reaction chamber by the action of ionization attributable to the plasma, and thereafter the pressure control means is operated to introduce the ionized gas into the film-forming chamber.

### BACKGROUND OF THE INVENTION

1. Field of the Invention

This invention relates to a vacuum deposition system for forming on substrates various functional films, films with semiconductor characteristics, films with optical characteristics and so forth, and a thin-film deposition process.

2. Related Background Art

In conventional vacuum deposition processes, when a deposition material is heated to deposit a film on a substrate, gas atoms in thin film formed have tended to come short to attain the desired film characteristics with difficulty. Accordingly, in order to compensate such gas atoms, it has been common to use an ion source to ionize the gas coming short and irradiate the thin film with the ionized gas to maintain the film quality. In this case, a Kaufmann type ion source, a linear-source ion source, a hollow-cathode ion source or the like is used as the ion source.

An example of a vacuum deposition system used in conventional thin-film deposition processes, having such an ion source inside the vacuum deposition system, is diagrammatically shown in FIG. 4.

This vacuum deposition system has a film-forming chamber the inside of which can be kept at a stated degree of vacuum by an evacuation means 130, and provided therein i) a crucible 106 which heats a deposition material 107 to be made into a thin film, ii) a Kaufmann type ion source 113 connected to an ionic-gas feed means 131 which feeds a source gas for compensating the gas atoms having come short and iii) a substrate holder 105 which holds a substrate 104 on which the thin film is to be formed.

Where, e.g., an MgF₂ film is formed on a quartz substrate 104 by means of this vacuum deposition system, an He-F mixed gas containing F₂ is introduced from the ionic-gas feed means 131 to the ion source 113. Ions generated by plasma caused to take place in this ion source 113 is jetted out of it through its jet-out opening 132 toward the substrate 104, during which the MgF₂ in the crucible 106 is simultaneously heated to evaporate it. Thus, the MgF₂ film comes to be formed on the substrate 104.

In the conventionally known technique making use of such an ion source, however, the energy of ions jetted out of the ion source is generally as high as hundreds of eV to thousands of eV, and hence the substrate and the thin film formed may be damaged.

The plasma caused to take place in the ion source tends to be diffused over the whole film-forming chamber from the jet-out opening through which the ions are jetted out, and the materials of inner-walls of the film-forming chamber may be sputtered by such ions. Because of this sputtering, the inner-wall materials may come included in the film as impurities. Also, since the substrate is exposed to the plasma, the substrate and the thin film formed may be damaged to impair film quality.

In addition, a filament material and a grid material which are used to form and accelerate ions are present in the ion source. Hence, they may be sputtered by ions to tend to come included in the film as impurities together with the ions.

As other conventionally known technique, the following means is available.

It is a method in which, in a system comprising a vacuum deposition chamber and an oxygen plasma generation chamber, oxygen plasma is caused to take place in the oxygen plasma generation chamber, and a dielectric thin film is formed while the oxygen plasma is fed into the vacuum deposition chamber through a guide path which connects the vacuum deposition chamber and the oxygen plasma generation chamber (Japanese Patent Application Laid-Open No. 8-60347).

According to this method, in the vacuum deposition chamber and the oxygen plasma generation chamber, their degree of vacuum is not independently controlled. This method can not make any optimum control of the degree of vacuum when the degree of vacuum which is suited for vacuum deposition and the degree of vacuum which is suited for plasma generation differ from each other.

### SUMMARY OF THE INVENTION

Accordingly, an object of the present invention is to provide a vacuum deposition system and a thin-film deposition process which enable deposition of thin films having less inclusion of impurities.

To achieve the above object, the vacuum deposition system of the present invention comprises a film-forming chamber to be kept at a stated degree of vacuum, and provided therein a substrate holder which holds a substrate and a vapor-generating means which generates a vapor of a deposition material which is to be vacuum-deposited on the surface of the substrate to come into a thin film, wherein,

the system comprises:

a reaction chamber provided therein with an ionization means which ionizes by the plasma a source gas for compensating atoms coming short in the thin film; and

a communicating portion which makes the inside of the film-forming chamber and the inside of the reaction chamber communicate with each other and has a pressure control means which controls differential pressure between the film-forming chamber and the reaction chamber.

The vacuum deposition system of the present invention, constructed as recited above, can ionize the source gas in the reaction chamber which is a chamber different from the film-forming chamber. Hence, the ion source for ionizing the source gas used to compensate the atoms coming short in the film need not be provided in the film-forming chamber in which the substrate is placed on which the thin film is to be formed. Thus, any sputtering of the film-forming chamber inner walls does not occur which may occur when the source gas is ionized by means of the ion source. Also, the pressure control means which controls differential pressure between the film-forming chamber and the reaction chamber can prevent as desired the plasma in the reaction chamber from diffusing to the film-forming chamber. Hence, any impurities which may otherwise be produced by sputtering in the film-forming chamber can be prevented from their inclusion in the film, or the substrate and film from exposure to the plasma.

The vacuum deposition system of the present invention may also be a system having a microwave-generating means for introducing microwaves into the reaction chamber. It may still also be a system having a high-frequency power source for supplying a high-frequency power into the reaction chamber. Also, the pressure control means may be a pressure control valve.

The vacuum deposition system of the present invention may also be a system having a gas feed means for feeding the source gas into the reaction chamber. In particular, the gas feed means may be a means for feeding into the reaction chamber at least one of oxygen gas and fluorine gas as the source gas.

The thin-film deposition process of the present invention is a thin-film deposition process which forms a thin film by means of the vacuum deposition system of the present invention, and comprises the steps of ionizing a source gas in the reaction chamber and thereafter opening the pressure control means of the communicating portion to introduce an ionized source gas into the film-forming chamber.

The thin-film deposition process of the present invention, as recited above, makes use of the vacuum deposition system of the present invention, and hence can ionize the source gas in the reaction chamber which is a chamber different from the film-forming chamber. Then, since it has the steps of ionizing the source gas in the reaction chamber and thereafter opening the pressure control means of the communicating portion to introduce the ionized source gas into the film-forming chamber, any sputtering of the film-forming chamber inner walls does not occur which may occur when the source gas is ionized in the film-forming chamber.

### BRIEF DESCRIPTION OF THE DRAWINGS

FIG. 1 is a diagrammatic illustration of an example of the vacuum deposition system according to the present invention.

FIG. 2 is a flow chart for describing a thin-film deposition process making use of the vacuum deposition system shown in FIG. 1.

FIG. 3 is a diagrammatic illustration of a vacuum deposition system used in Examples of the present invention.

FIG. 4 is a diagrammatic illustration of a conventional vacuum deposition system.

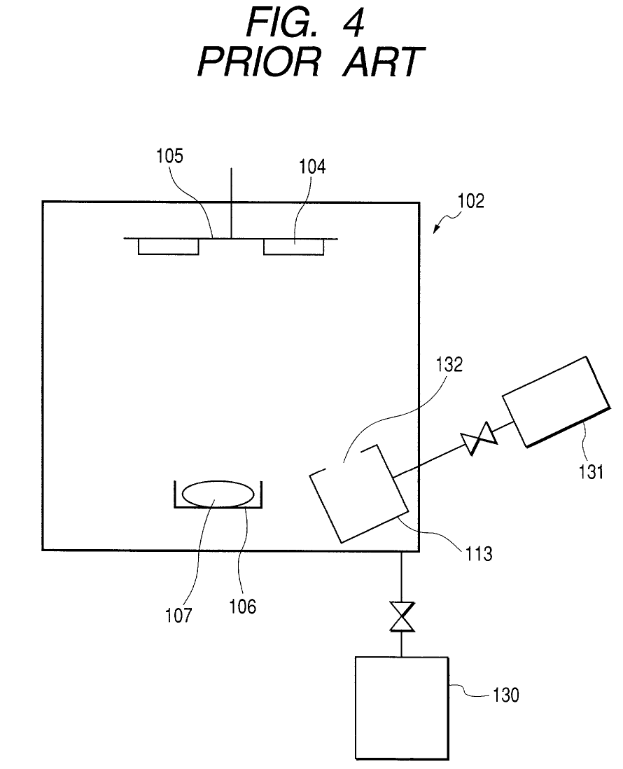

### DETAILED DESCRIPTION OF THE PREFERRED EMBODIMENTS

Embodiments of the present invention are described below with reference to the accompanying drawings.

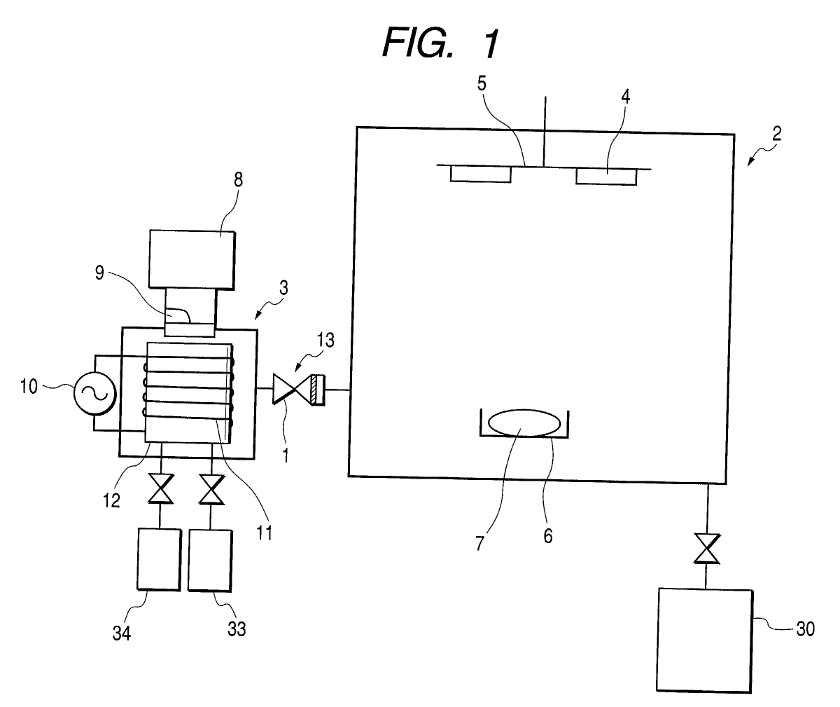

FIG. 1 diagrammatically illustrates an example of the vacuum deposition system according to the present invention.

The vacuum deposition system has i) a film-forming chamber 2 the inside of which can be kept at a stated degree of vacuum by a film-forming chamber evacuation means 30 such as a vacuum pump, having a substrate holder 5 which holds a substrate 4 on which a thin film is to be formed and a crucible 6 which heats and evaporates a deposition material 7 to be made into a thin film, and ii) a reaction chamber 3 in the inside of which a gas is to be ionized, which is connected to a reaction chamber gas feed means 34 which feeds a source gas for compensating gas atoms having come short. These film-forming chamber 2 and the reaction chamber 3 are connected through a communicating portion 13 having a butterfly valve 1 which is a pressure control valve for controlling differential pressure between the film-forming chamber 2 and the reaction chamber 3.

To the reaction chamber 3, also connected are a reaction chamber evacuation means 33 such as a vacuum pump for bringing its inside to a stated degree of vacuum, a microwave power source 8 and a high-frequency power source 10.

Microwaves from the microwave power source 8 are guided into the reaction chamber 3 through a quartz window 9. High-frequency power supplied from the high-frequency power source 10 is applied to a coil electrode 11 wound on a quartz tube 12.

As the gas fed from the reaction chamber gas feed means 34, a gas matching the deposition material 7 to be heated and evaporated in the crucible 6, i.e., the thin film to be formed on the substrate 4, is fed. For example, where the deposition material 7 is an oxide such as TiO₂ or Al₂O₃, it is preferable to feed a mixed gas of Ar and O₂ or an O₂ gas; and, where the deposition material 7 is MgF₂ or LaF₃, a mixed gas of He and F or an F₂ gas. Examples are by no means limited to these.

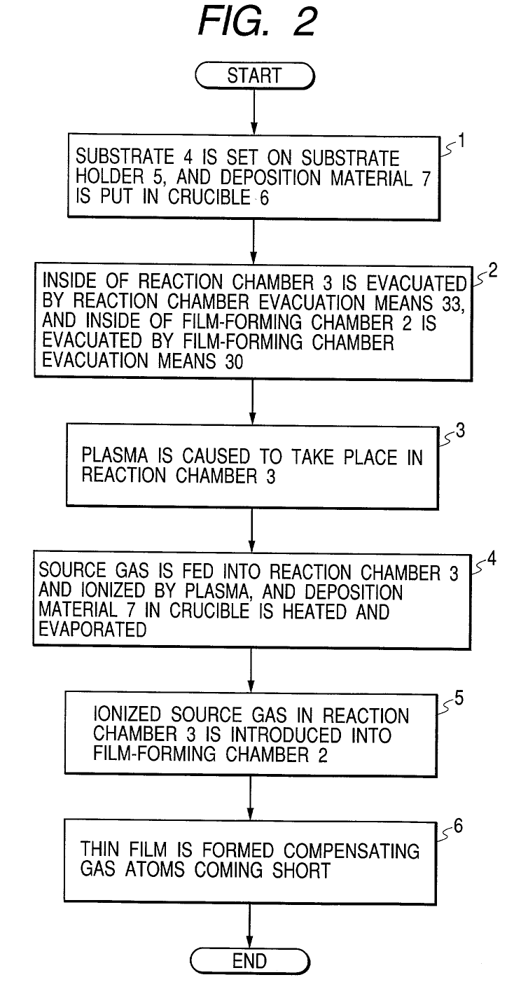

The thin-film deposition process is described below with reference to the flow chart shown in FIG. 2.

First, the substrate 4 on which the thin film is to be formed is set on the substrate holder 2, and the deposition material 7 to be made into the thin film is put in the crucible 6 (Step 1).

Next, the inside of the reaction chamber 3 is evacuated to a stated degree of vacuum by the reaction chamber evacuation means 33, and also the inside of the film-forming chamber 2 is simultaneously evacuated to a stated degree of vacuum by the film-forming chamber evacuation means 30 (Step 2).

Next, the microwaves are guided from the microwave power source 8 into the reaction chamber 3 through the quartz window 9, and also the high-frequency power supplied from the high-frequency power source 10 is applied to the coil electrode 11 to produce a magnetic field. This causes discharge in the reaction chamber 3 to cause plasma to take place therein (Step 3).

Next, the source gas is fed into the reaction chamber 3 by the reaction chamber gas feed means 34, and also the deposition material 7 in the crucible 6 is heated and evaporated by a heating means (not shown) (Step 4).

Next, the source gas in the reaction chamber 3, having been ionized by the action of ionization attributable to the plasma, is introduced into the film-forming chamber 2 by opening the butterfly valve 1 (Step 5).

Then, the gas having been ionized in the reaction chamber 3 brings about formation of the thin film while compensating the gas atoms which may come short when formed relying only the deposition material 7 evaporated off the crucible 6 (Step 6).

In the film-forming chamber 2, the thin film become low-density to have a poorer film quality with an increase in the probability at which the deposition material having flown from the deposition source collides against gas molecules and so forth to scatter. Hence, its inside must be brought to a pressure as low as possible. Stated specifically, its inside may preferably be evacuated to 13 mPa or less.

On the other hand, in the reaction chamber 3, the plasma may take place with difficulty at a low pressure, and hence its inside must be kept at a high pressure to a certain degree, being filled with the gas. From the viewpoint of keeping as far as possible the film from being damaged, too, the energy of ions and so forth should be kept low, and hence the gas pressure must be made high to a certain degree. Too high a pressure, however, may conversely make the probability higher at which the ions and active species intended to be introduced into the film-forming deposition chamber are scattered by gas molecules to have a small mean free path to come extinct at last. Accordingly, the internal pressure of the reaction chamber 3 may preferably be in the range of from 0.3 Pa to 7 Pa.

As described above, in the vacuum deposition system of the present invention, the source gas for compensating the gas atoms coming short is not ionized in the film-forming chamber 2 but in the reaction chamber 3 which is a chamber different from the film-forming chamber 2. Then, the gas having been ionized in the reaction chamber 3 is introduced into the reaction chamber 3, where the thin film is formed compensating the gas atoms coming short. Thus, the problems can be avoided which may occur when the ion source is provided in the film-forming chamber to effect ionization.

For example, impurities can be kept from coming included in the thin film, i.e., the impurities produced when the filament material and grid material provided in the ion source or the inner-walls of the film-forming chamber are sputtered by ions. Then, the film can also be kept from being damaged by the energy of ions jetted out of the ion source. Also, the energy of ions in the reaction chamber is generally as low as tens of eV to hundreds of eV, and hence the substrate and the film formed may less be damaged. Thus, the vacuum deposition system of the present invention enables deposition of thin films having less damage and less inclusion of impurities, in other words, small optical absorbance.

Examples of the embodiments of the present invention are given below. The present invention should by no means be construed limitative by these.

(First Example)

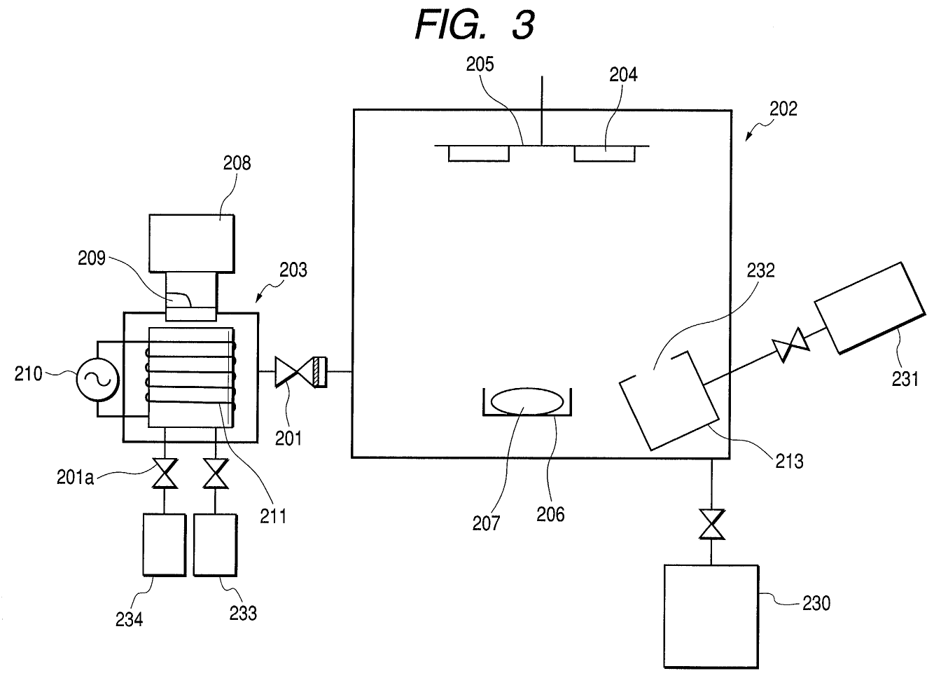

FIG. 3 diagrammatically illustrates a vacuum deposition system used in this Example.

The vacuum deposition system used in this Example has a reaction chamber 203, and also is provided with an ion source 213 in a film-forming chamber 202 so that a case where the source gas is ionized in the reaction chamber 203 to effect film formation can be compared with a case where the source gas is ionized in the film-forming chamber 202 to effect film formation. Namely, in the case where the source gas is ionized in the reaction chamber 203, the ion source 213 provided in the film-forming chamber 202 is not used. On the other hand, in the case where the source gas is ionized using the ion source 213 in the film-forming chamber 202, the reaction chamber 203 is not used. The vacuum deposition system used in this Example has basically the same construction as the vacuum deposition system shown in FIG. 1 in the above embodiment, and hence its detailed description is not repeated.

Conditions for the thin-film deposition in this Example are shown below.

As substrates 204, two types were used, an optical-glass BK-7 substrate and a polycarbonate (PC) substrate, and these were both set held on a substrate holder 205 in order.

As a deposition material 207, TiO₂ was used. This was put in a crucible 206, and was heated and evaporated.

The internal pressure of the film-forming chamber 202 was set to 7×10⁻⁴ Pa by means of a film-forming chamber evacuation means 230.

As a source gas to be fed into the reaction chamber 203 from a reaction chamber gas feed means 234, a mixed gas of Ar and O₂ in a ratio of 4:1 was introduced. This mixed gas was made to flow into the reaction chamber 203 while a butterfly valve 201a was so controlled that the internal pressure of the reaction chamber 203 having previously been evacuated by means of a reaction chamber evacuation means 233 came to 0.53 Pa.

To a coil electrode 211, RF (radio frequency) power of 300 W was applied from a high-frequency power source 210 to produce an electric field to cause plasma to take place, to ionize the Ar and O₂ gases.

Under the above conditions, the TiO₂ in the crucible 206 was heated and evaporated, during which the butterfly valve 201 was opened and the ionized Ar and O₂ gases were introduced into the film-forming chamber 202 from the reaction chamber 203. Thus, TiO₂ films of 100 nm in film thickness were formed on both the substrates 204, the BK-7 substrate and the polycarbonate (PC) substrate.

(First Comparative Example)

As Comparative Example of First Example, thin films were formed using the ion source 213 provided in the film-forming chamber 202, without using the reaction chamber 203 of the vacuum deposition system used in First Example. More specifically, a mixed gas of Ar and O₂ was fed from an ion source gas feed means 231. The gas was ionized in the ion source 213 provided in the film-forming chamber 202 and the ionized gas was jetted out through its jet-out opening 232 to form TiO₂ films of 100 nm in film thickness on both the substrates 204, the BK-7 substrate and the polycarbonate (PC) substrate, under the same conditions as those in First Example.

The thin films thus respectively formed in First Example and First Comparative Example were each put to a spectrometer to measure their transmittance and reflectance, and optical absorbance (100%−(transmittance+reflectance)) at a wavelength of 500 nm was calculated. Results obtained are shown in Table 1. Incidentally, the optical absorbance is the total value of the absorption in the substrate and the absorption in the film formed thereon.

TABLE 1

| | BK-7 substrate | PC substrate |
|---|---|---|
| First Example: | 0.02% | 0.02% |
| (Reaction chamber is used.) | | |
| First Comparative Example: | 0.03% | 0.45% |
| (Ion source is used.) | | |

In the case of the BK-7 substrates with TiO₂ film, any remarkable difference in optical absorbance was not seen between First Example and First Comparative Example. In the case of the PC substrate, however, First Comparative Example, in which the ion source was used, showed a much greater optical absorbance.

Thus, from the fact that the difference was seen only in the optical absorbance of the PC substrates, it was ascertained that the PC substrate tended to be damaged when the film was formed using the ion source and was less damaged when the film was formed using the reaction chamber.

Impurities in film were also analyzed by SIMS (secondary ion mass spectroscopy). As a result, constituent substances of stainless steel materials, such as W, Fe, Co and Ni, were seen in the TiO₂ films formed using the ion source in First Comparative Example, but none of them were seen in the TiO₂ films formed using the reaction chamber in First Example.

(Second Example)

In this Example, thin films were formed by means of the vacuum deposition system used in First Example.

Conditions for the thin-film deposition in this Example are shown below.

As the substrates 204, two types were used, a quartz substrate and a fluorite substrate.

As the deposition material 207, Al₂O₃ was put in the crucible 206.

The internal pressure of the film-forming chamber 202 was set to 7×10⁻⁴ Pa by means of the film-forming chamber evacuation means 230.

As the source gas to be fed into the reaction chamber 203 from the reaction chamber gas feed means 234, O₂ gas was introduced. This O₂ gas was made to flow into the reaction chamber 203 while the butterfly valve 201a was so controlled that the internal pressure of the reaction chamber 203 having previously been evacuated by means of the reaction chamber evacuation means 233 came to 0.53 Pa.

To the coil electrode 211, RF power of 300 W was applied from the high-frequency power source 210 to produce an electric field to cause plasma to take place, to ionize the O₂ gas.

Under the above conditions, the Al₂O₃ in the crucible 206 was heated and evaporated, during which the butterfly valve 201 was opened and the ionized O₂ gas was introduced into the film-forming chamber 202 from the reaction chamber 203. Thus, Al₂O₃ films of 100 nm in film thickness were formed on both the substrates 204, the quartz substrate and the fluorite substrate.

(Second Comparative Example)

As Comparative Example of Second Example, thin films were formed using the ion source 213 provided in the film-forming chamber 202, without using the reaction chamber 203 of the vacuum deposition system used in Second Example. More specifically, O₂ gas was fed from the ion source gas feed means 231. The gas was ionized in the ion source 213 and the ionized gas was jetted out through its jet-out opening 232 to form Al₂O₃ films of 100 nm in film thickness on both the substrates 204, the quartz substrate and the fluorite substrate, under the same conditions as those in Second Example.

The thin films thus respectively formed in Second Example and Second Comparative Example were each put to a spectrometer to measure their transmittance and reflectance, and optical absorbance at a wavelength of 193 nm was calculated. Results obtained are shown in Table 2. Incidentally, the optical absorbance is the total value of the absorption in the substrate and the absorption in the film formed thereon.

TABLE 2

| | Quartz | Fluorite |
|---|---|---|
| | substrate | substrate |
| Second Example: | 0.10% | 0.12% |
| (Reaction chamber is used.) | | |
| Second Comparative Example: | 0.33% | 0.67% |
| (Ion source is used.) | | |

In the case of the quartz substrates with Al₂O₃ film, good thin films having a smaller optical absorbance were able to be formed when the reaction chamber was used.

The fluorite substrates with Al₂O₃ film also showed a much greater optical absorbance when the ion source was used.

Thus, it was ascertained that the fluorite substrate tended to be damaged when the film was formed using the ion source and the fluorite substrate was less damaged when the film was formed using the reaction chamber.

(Third Example)

In this Example, too, thin films were formed by means of the vacuum deposition system used in First Example.

Conditions for the thin-film deposition in this Example are shown below.

As the substrates 204, two types were used, a quartz substrate and a fluorite substrate.

As the deposition material 207, MgF₂ was put in the crucible 206.

The internal pressure of the film-forming chamber 202 was set to 7×10⁻⁴ Pa by means of the film-forming chamber evacuation means 230.

As the source gas to be fed into the reaction chamber 203 from the reaction chamber gas feed means 234, an He-F mixed gas with an F₂ content of 5% was introduced. This mixed gas was made to flow into the reaction chamber 203 while the butterfly valve 201a was so controlled that the internal pressure of the reaction chamber 203 having previously been evacuated by means of the reaction chamber evacuation means 233 came to 0.93 Pa.

A microwave power of 500 W was applied from a microwave power source 208 to introduce microwaves into the reaction chamber 203 to cause plasma to take place, to ionize the He-F mixed gas with an F₂ content of 5%.

Under the above conditions, the MgF₂ in the crucible 206 was heated and evaporated, during which the butterfly valve 201 was opened and the ionized He-F mixed gas with an F₂ content of 5% was introduced into the film-forming chamber 202 from the reaction chamber 203. Thus, MgF₂ films of 100 nm in film thickness were formed on both the substrates 204, the quartz substrate and the fluorite substrate.

(Third Comparative Example)

As Comparative Example of Third Example, thin films were formed using the ion source 213 provided in the film-forming chamber 202, without using the reaction chamber 203 of the vacuum deposition system used in Third Example. More specifically, He-F mixed gas with an F₂ content of 5% was fed from the ion source gas feed means 231. The gas was ionized in the ion source 213 and the ionized gas was jetted out through its jet-out opening 232 to form MgF₂ films of 100 nm in film thickness on both the substrates 204, the quartz substrate and the fluorite substrate, under the same conditions as those in Third Example.

The thin films thus respectively formed in Third Example and Third Comparative Example were each put to a spectrometer to measure their transmittance and reflectance, and optical absorbance at a wavelength of 157 nm was calculated. Results obtained are shown in Table 3. Incidentally, the optical absorbance is the total value of the absorption in the substrate and the absorption in the film formed thereon.

TABLE 3

| | Quartz | Fluorite |
|---|---|---|
| | substrate | substrate |
| Third Example: | 0.10% | 0.12% |
| (Reaction chamber is used.) | | |
| Third Comparative Example: | 0.46% | 0.75% |
| (Ion source is used.) | | |

In the case of the quartz substrates with MgF₂ film, good thin films having a smaller optical absorbance were able to be formed when the reaction chamber was used.

The fluorite substrates with MgF₂ film also showed a much greater optical absorbance when the ion source was used.

Thus, it was ascertained that the fluorite substrate tended to be damaged when the film was formed using the ion source and the fluorite substrate was less damaged when the film was formed using the reaction chamber.

The films formed were further compositionally analyzed by ESCA (soft X-ray, electron spectroscopy for chemical analysis). As a result, the films formed using the ion source was in a ratio of Mg to F of 1:1.4, and those formed using the reaction chamber was in a ratio of Mg to F of 1:1.8. Thus, it was ascertained that the MgF₂ films formed using the ion source stood short in F atoms in film because of the damage due to ions.

(Fourth Example)

In this Example, thin films were formed by means of the vacuum deposition system used in First Example.

Conditions for the thin-film deposition in this Example are shown below. As the substrates 204, two types were used, a quartz substrate and a fluorite substrate.

As the deposition material 207, LaF₃ was put in the crucible 206.

The internal pressure of the film-forming chamber 202 was set to 7×10⁻⁴ Pa by means of the film-forming chamber evacuation means 230.

As the source gas to be fed into the reaction chamber 203 from the reaction chamber gas feed means 234, an Ar-F mixed gas with an F₂ content of 5% was introduced. This mixed gas was made to flow into the reaction chamber 203 while the butterfly valve 201a was so controlled that the internal pressure of the reaction chamber 203 having previously been evacuated by means of the reaction chamber evacuation means 233 came to 0.93 Pa.

A microwave power of 500 W was applied from the microwave power source 208 to introduce microwaves into the reaction chamber 203 through quartz window 209 to cause plasma to take place, to ionize the Ar-F mixed gas with an F₂ content of 5%.

Under the above conditions, the LaF₃ in the crucible 206 was heated and evaporated, during which the butterfly valve 201 was opened and the ionized Ar-F mixed gas with an F₂ content of 5% was introduced into the film-forming chamber 202 from the reaction chamber 203. Thus, LaF₃ films of 100 nm in film thickness were formed on both the substrates 204, the quartz substrate and the fluorite substrate.

(Fourth Comparative Example)

As Comparative Example of Fourth Example, thin films were formed using the ion source 213 provided in the film-forming chamber 202, without using the reaction chamber 203 of the vacuum deposition system used in Fourth Example. More specifically, Ar-F mixed gas with an F₂ content of 5% was fed from the ion source gas feed means 231. The gas was ionized in the ion source 213 and the ionized gas was jetted out through its jet-out opening 232 to form LaF₃ films of 100 nm in film thickness on both the substrates 204, the quartz substrate and the fluorite substrate, under the same conditions as those in Fourth Example.

The thin films thus respectively formed in Fourth Example and Fourth Comparative Example were each put to a spectrometer to measure their transmittance and reflectance, and optical absorbance at a wavelength of 157 nm was calculated. Results obtained are shown in Table 4. Incidentally, the optical absorbance is the total value of the absorption in the substrate and the absorption in the film formed thereon.

TABLE 4

| | Quartz | Fluorite |
|---|---|---|
| | substrate | substrate |
| Fourth Example: | 0.20% | 0.22% |
| (Reaction chamber is used.) | | |
| Fourth Comparative Example: | 0.73% | 1.26% |
| (Ion source is used.) | | |

In the case of the quartz substrates with LaF₃ film, good thin films having a smaller optical absorbance were able to be formed when the reaction chamber was used.

The fluorite substrates with LaF₃ film also showed a much greater optical absorbance when the ion source was used.

Thus, it was ascertained that the fluorite substrate tended to be damaged when the film was formed using the ion source and the fluorite substrate was less damaged when the film was formed using the reaction chamber.

With regard to AlF₃, HoF, YF₃, NdF₃ and GdF₃ films, too, good thin films having a smaller optical absorbance were also able to be formed when the reaction chamber was used.

As described above, in the present invention, the source gas is ionized in the reaction chamber which is a chamber different from the film-forming chamber, and, after the source gas has been ionized in the reaction chamber, the pressure control means of the communicating portion is opened to introduce the ionized gas into the film-forming chamber. Hence, the plasma in the reaction chamber can be prevented from diffusing to the film-forming chamber, and any impurities which may otherwise be produced by sputtering in the film-forming chamber can be prevented from their inclusion in the film, or the substrate and film from exposure to the plasma. Thus, thin films having less inclusion of impurities and thin films having less damage due to plasma can be formed.

What is claimed is:

1. A vacuum deposition system comprising a film-forming chamber to be kept at a stated degree of vacuum, and provided therein a substrate holder which holds a substrate and a vapor-generating means which generates a vapor of a deposition material which is to be vacuum-deposited on the surface of the substrate to come into a thin film, the system further comprising:
a reaction chamber provided therein with an ionization means which ionizes by the plasma a source gas for compensating atoms coming short in the thin film; and
a communicating portion which makes the inside of the film-forming chamber and the inside of the reaction chamber communicate with each other and has a pressure control means which controls differential pressure between the film-forming chamber and the reaction chamber.

2. The vacuum deposition system according to claim 1, which comprises a microwave-generating means for introducing microwaves into the reaction chamber.

3. The vacuum deposition system according to claim 1, which comprises a high-frequency power source for supplying a high-frequency power into the reaction chamber.

4. The vacuum deposition system according to claim 1, wherein the pressure control means is a pressure control valve.

5. The vacuum deposition system according to claim 1, which comprises a gas feed means for feeding the source gas into the reaction chamber.

6. The vacuum deposition system according to claim 5, wherein the gas feed means is a means for feeding into the reaction chamber at least one of oxygen gas and fluorine gas as the source gas.

7. A thin-film deposition process which forms a thin film by means of the vacuum deposition system according to claim 1, the process comprising the steps of:
ionizing the source gas in the reaction chamber and thereafter opening the pressure control means of the communicating portion to introduce an ionized source gas into the film-forming chamber; and
generating a vapor of the deposition material in the film-forming chamber to form the thin film.

8. The thin-film deposition process according to claim 7, wherein the film-forming chamber is kept at an internal pressure of 13 mPa or less, and the reaction chamber is kept at an internal pressure of from 0.3 Pa to 7 Pa.
